(19) United States
(12) Patent Application Publication
(10) Pub. No.: US 2009/0309623 A1
(43) Pub. Date: Dec. 17, 2009

(54) Method for Assessment of Material Defects

(75) Inventors: Orin W. Holland, Maryville, TN (US); Terry D. Golding, Corinth, TX (US); Ronald P. Hellmer, Round Rock, TX (US); Thomas H. Myers, Morgantown, WV (US)

Correspondence Address: BURLESON COOKE L.L.P., 2040 NORTH LOOP 336 WEST, SUITE 123, CONROE, TX, 77304, US

(73) Assignee: Amethyst Research, Inc., Ardmore, OK (US)

(21) Appl. No.: 12/137,151

(22) Filed: Jun. 11, 2008

(51) Int. Cl. G01R 31/26

(52) U.S. Cl. 324/765

(57) ABSTRACT

A method is provided for measuring defects in semiconductor materials. In one embodiment the method includes placing deuterium in the material and directing an ion beam onto the material to cause a nuclear reaction with the deuterium. Products of the nuclear reaction are analyzed (NRA) to measure the concentration of defects. In other embodiments, a spectroscopic technique is used to detect the deuterium taggant. Lattice defect or total defect occurrences can be selected by selecting the method of placing deuterium in the sample. Defect concentration vs. depth below the surface of material can be determined by varying the energy of the ion beam or by measuring energy profiles of products of the nuclear reaction. The method may be applied to wafers, pixels or other forms of semiconductor materials and may be combined with X-ray analysis of elements on the material.

### BACKGROUND OF THE INVENTION

1. Field of the Invention

This invention pertains to a method for assessment and characterization of lattice defects in semiconductors. More specifically, method is provided for chemically tagging the material with an isotope of hydrogen, preferably deuterium, and then detecting the isotope, preferably by use of an energetic ion-beam to induce a nuclear reaction.

2. Description of Related Art

Global competitiveness of the microelectronics market has led to ever-increasing demands for improved manufacturing yields. These demands have been satisfied, in part, through use of sophisticated metrology tools for both material assessment and in-line process monitoring. Real-time inspection allows the manufacturer to detect processing errors or a drift outside specifications, both of which can decrease yields or lead to catastrophic losses. A case-in-point involved the elimination of implant-related zero-yield wafers in a high-performance, very-large-scale integration (VLSI) CMOS production line. The introduction of an in-line metrology to monitor the implantation process essentially eliminated the average yield loss of five percent in the production line due to zero-yield wafers. U.S. Pat. No. 7,119,569 and U.S. Pat. Pub. No. 2004/0191936 discloses methods for real-time testing of semiconductor wafers.

Nowhere is the loss of yield—due in part to the absence of appropriate metrology tools—more critical than in the production of infrared focal-plane arrays (IRFPAs) based on II-VI or III-V semiconductors. Such production is critical to meet the significant demand for improved detectors across the infrared (IR) spectrum, particularly in terms of increased spectral range, pixel sensitivity, pixel density and functionality (e.g. multi-spectral sensors). Since its bandgap can be continuously adjusted by varying the alloy composition (Hg to Cd ratio), HgCdTe (MCT) is a Group II-VI compound semiconductor that is commonly used for sensors with cutoff wavelengths ranging from short wavelength or near infrared (NIR, SWFR: 1-2 μm) to long wavelength (LWIR: 8-12 μm) and very long wavelength (VLWIR: 12-16 μm). HgCdTe growth techniques and material quality issues are summarized in “HgCdTe on Si: Present Status and Novel Buffer Layer Concepts,” T. D. Golding, O. W. Holland, et al, J. Electron. Mater. 32 882 (2003). Poor material quality and the lack of in-line process control in IRFPA production have a severe impact on manufacturing yields. It is clear that even marginal improvements in either material quality or process control would result in significant economic benefits.

There is a particular need for improved and more sensitive methods to measure the amount and types of defects in semiconductor materials and devices. Such capabilities will allow production of improved devices with higher yield and thus lower cost by providing methods to evaluate defects in materials during manufacturing processes and in finished semiconductor products.

### SUMMARY OF INVENTION

The preferred defect-mapping method disclosed herein combines two processes: (1) use of deuterium or other hydrogen isotopes for “decoration” or “tagging” of lattice defects in materials and (2) the use of a spectroscopic technique, such as Nuclear Reaction Analysis (NRA), to detect deuterium or other hydrogen isotopes and thereby map the density and distribution of defects in the material. Other methods, such as secondary ion mass spectroscopy (SIMS), elastic recoil detection (END) and Raman spectroscopy may also be used to detect deuterium or other isotopes.

The method of hydrogen isotope tagging may be achieved by a plasma-enhanced or a UV-illumination-enhanced process or a combination of both processes. The method for enhancing the process of sample tagging may be varied to select the type of defect for tagging. A number of reactions involving different ion type and energy can be used to detect deuterium but the use of “helium 3” ions is preferred. (“Helium 3” refers to the isotope of helium with an atomic mass number of 3, i.e., ³He.) The beam energy and the detectors to measure the resulting emissions from a sample during NRA may be chosen to facilitate the measurement of defects at different depths in a sample or the beam may be focused to a small area for defect detection within a laterally restricted area of a material wafer or within a pixel of a detector array. Measurements of impurities may be combined with defect assessment.

### BRIEF DESCRIPTION OF THE DRAWINGS

FIG. 1A is a graph showing deuterium concentration vs depth in a Hg₁₋ₓCdₓTe/Hg_{1-y}Cd_{y}Te/CdTe/Si heterostructure grown in situ. FIG. 1B is a graph showing deuterium concentration vs. depth in a Hg₁₋ₓCdₓTe/Hg_{1-y}Cd_{y}Te/CdTe/Si heterostructure grown ex situ.

FIG. 2 is a sketch of apparatus suitable for plasma-enhanced deuteration of a sample.

FIG. 3 is a sketch of apparatus suitable for photon-assisted deuteration of a sample using UV radiation.

FIG. 4 is a diagram of the particles involved in the ³He-D nuclear reaction including the incident ³He-ion and the target D, as well as the ⁴He and ¹H reaction products.

FIG. 5A is a sketch of an incident ion-beam impinging on a sample and an annular detector. FIG. 5B is a sketch of an incident ion-beam impinging on a sample and a planar detector.

FIG. 6 is a sketch of apparatus for measuring the energy of emissions during NRA of a sample.

FIG. 7A is a sketch showing mapping of deuterium on a small scale from a focused beam. FIG. 7B is a sketch showing mapping of deuterium on a larger scale from an unfocused beam. FIG. 7C is a sketch showing mapping of deuterium on a smaller and larger scale for assessing defects.

FIG. 8 is a simulated histogram of counts from the nuclear reaction illustrated in FIG. 4 with a target deuterated with 1.5×10¹⁴D/cm².

FIG. 9 illustrates a detector-sample configuration required for depth profiling of isotopes.

FIG. 10A illustrates a pixelated target scanned by an ion beam. FIG. 10B illustrates a deuterium map of a pixel.

### DETAILED DESCRIPTION

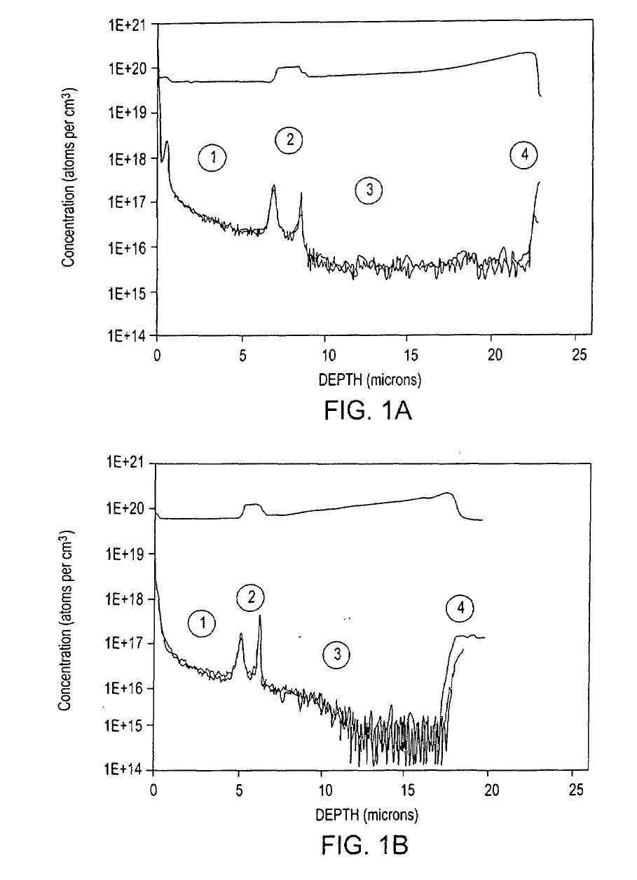

To illustrate the concept of deuterium (D) “decoration” or “tagging” of defects, SIMS (Secondary Ion Mass Spectrometry) depth profiles of D and tellerium (Te) in two deuterated heterostructures with the same basic construction, i.e. Hg₁₋ₓCdₓTe/Hg_{1-y}Cd_{y}Te/CdTe/Si, are shown in FIGS. 1A and 1B. Both heterostructures were deuterated by use of an RF-plasma, a process to be described below. The location of the Hg₁₋ₓCdₓTe layer or the active device layer in the heterostructures is designated as zone 1 of the graph, while the Hg₁₋ₓCd_{y}Te transition layer is designated as zone 2. Each will be referred to as MCT(x) and MCT(y), respectively, to denote the different (Hg₁₋ₓ, Hg_{1-y}) compositions. A CdTe buffer layer comprises zone 3, while the silicon substrate is in zone 4. The buffer layer has a lattice constant smaller than HgCdTe but larger than Si, and it is grown quite thick to reduce the as-grown dislocation density that arises due to lattice mismatch. The in-situ sample profiled in FIG. 1A was in situ grown, i.e., heterostructure growth was carried out in a single pass through the MBE (Molecular Beam Epitaxy) chamber without vacuum interruption. The sample profiled in FIG. 1B was ex-situ grown in two separate MBE chambers: one for growing the CdTe/Si buffer layer, and the other for growing the MCT layers.

The data show that defect decoration by deuterium is not limited to specific defect morphology but is quite general and not material-dependent. (However, techniques will be discussed below that demonstrate that deuterium can be introduced selectively into a semiconductor along a line defect, such as a dislocation.) Deuteration occurs throughout the heterostructure and provides clear delineation of the various layers and their interfaces. The data also show that the quality of the HgCdTe device epilayer is rather independent of the quality of the CdTe/Si buffer layer—a surprising result. This can be seen by comparing the D concentration in the CdTe buffer layer (zone 3) with that in MCT(x) epilayer (zone 1). There is little or no correlation in the ratio of these concentrations in the two samples shown in FIG. 1.

The data also show that the deuterium concentration at both MCT(y) interfaces is very high—a clear indication of a high defect density. Furthermore, the defectivity at the MCT(x)/MCT(y) interface can be seen to extend spatially into the MCT(x) device layer (as indicated by the width of the interfacial region). SEM imaging (not shown) indicated that this may be due to a high density of Te precipitates, which were seen to be distributed inhomogeneously at this interface. Interestingly, the quality of the device layer (zone 1) appears to be more correlated with the defect density at the MCT(x/y) interface than the quality of the buffer layer.

The method disclosed herein is a quantitative materials characterization technique that depends on the ability of hydrogen (or more specifically, deuterium) to bind with a wide range of defects in semiconductors. (In the following, it should be understood that no distinction is implied or intended between hydrogen and its isotope deuterium, unless otherwise stated.) The trapping of hydrogen in semiconductors generally occurs as a result of chemical binding to dangling bonds related to defects or possibly physical adsorption in regions of dilation associated with defects. Therefore, the concentration profile of hydrogen in materials can be considered to be a rather faithful representation of the distribution of lattice disorder in semiconductors. The process of hydrogen decoration of defects is referred to as defect “tagging.” NRA is more easily accomplished with deuterium tagging, since the use of deuterium does not suffer from spurious effects due to the ubiquitous presence of hydrogen in the environment. Also, the deuterium nuclear reaction, involving the use of an energetic ³He, has a large reaction cross-section and leads to minimal lattice displacements due to the use of the light ion. Therefore, deuterium is the preferred isotope of hydrogen for use in chemical tagging of defects in the method of this invention.

The sensitivity of the method disclosed herein is limited by only the equilibrium concentration of hydrogen in materials. It is further limited by the total ion fluence used in the NRA measurement in those cases where the amount of ion-induced damage must be limited to ensure little or no impact on the physical or electrical properties of the sample. In general, it is impossible to experimentally determine the equilibrium concentration of interstitially dissolved hydrogen in semiconductors, since hydrogen so readily binds to defects—the basis of this invention. Therefore, any measurement will overwhelmingly yield the defect concentration rather than the equilibrium hydrogen concentration. However, it is believed that the equilibrium concentration below 100° C. is generally less than 10¹⁴ per cm⁻³ in semiconductors, which establishes the detection limit for the method disclosed here. By comparison, physical characterization of defects in semiconductors by another technique, known as Ion-Channeling, is limited to defect concentrations greater than 10²⁰ per cm⁻³. Thus, the sensitivity of this technique is less by 6-7 orders of magnitude than the detection method embodied within this invention.

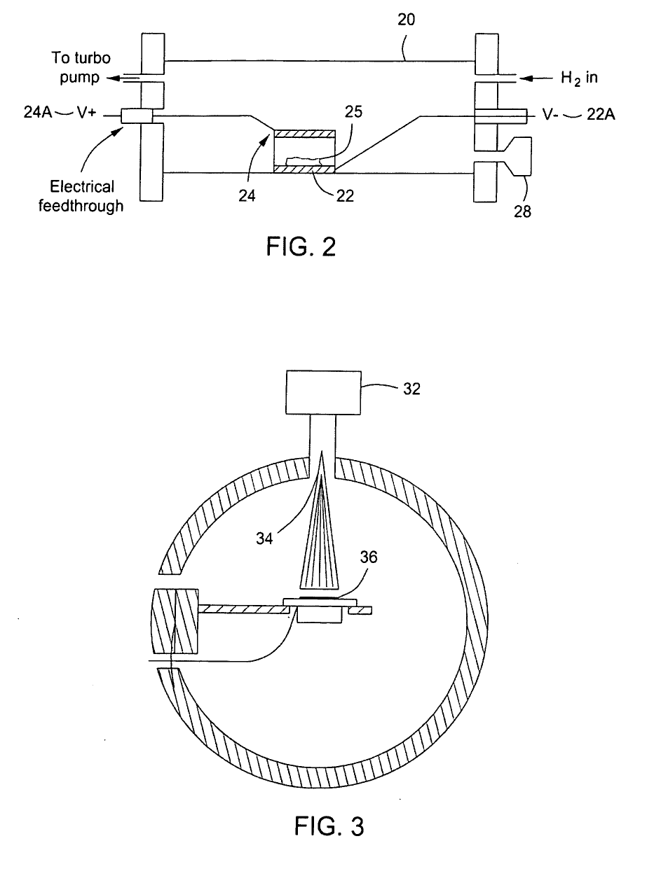

In general, any method for deuterating materials can be used to treat materials prior to NRA analysis. For the purposes of this invention, only two methods will be considered-plasma-enhanced and UV-enhanced deuteration. There are variations of each method. For instance, plasma processing of materials can be achieved using either a DC or RF application of voltage. FIG. 2 illustrates apparatus suitable for plasma-enhanced deuteration. Vacuum enclosure 20 contains cathode 22 and anode 24, having leads 22A and 24A, and pressure gage 28. Sample 25 of material to be deuterated may be placed in the plasma. Gas pressures in the range from about 1200 Torr to about 2000 Torr may be used at power levels from about 2 to 12 watts, for example. For AC operation, cathode 22 is grounded. Sample 25 may be immersed within the hydrogen plasma, as shown, or be removed from direct contact. The advantage of using an indirect or remote plasma treatment is that is does not damage the surface of the sample.

Alternatively, UV-activated deuteration may be achieved simply by irradiating samples in a hydrogen (deuterium) atmosphere at a selected temperature with a UV-lamp, which can be chosen for light frequency and intensity, as disclosed in commonly owned pending U.S. patent application Ser. No. 11/716,205. It has been shown that the wavelength (frequency) of the light affects the kinetics of the hydrogenation process, and that it is more effective at shorter wavelengths. A sketch of apparatus suitable for UV-enhanced deuteration, as disclosed in the cited patent application, is shown as FIG. 3. Lamp 32 may be a deuterium lamp made by Hammamatsu, which is especially suited for UV-enhanced deuteration. In addition to shorter wavelength output than other UV lamps, the lamp comes mounted inside a conflat vacuum flange for mounting to a vacuum chamber. It has a dominant spectral range of 115-170 nm. This allows direct illumination of sample 36 through magnesium fluoride window 34. Other UV lamps and windows may be employed.

There are distinct differences in the mode or pathways activated for hydrogen in-diffusion of semiconductors by these two deuteration techniques. Most semiconductors possess open lattices such as the diamond, zincblende or the wurzite lattice, which allow atomic hydrogen to dissolve and quickly diffuse interstitially. The equilibrium concentration of dissolved hydrogen depends on charge state (±, o), as determined by the Fermi energy in the semiconductor. In general, dissolved hydrogen tends to reduce the conductivity of the semiconductor, so that the H⁻ acceptor is predominately found in n-type material, and the H⁺ donor in p-type, although this is not always the case. Therefore, hydrogen atoms diffuse by hopping along interstitially-connected pathways within the bulk crystal. Thus, hydrogen can diffuse either as H⁻, H⁺, or neutral H. It should be understood that H⁺ diffuses much faster than either of its other forms since it is physically much smaller.

Alternatively, there are other pathways for hydrogen diffusion in semiconductors that are predominately provided by dislocations. Open volume within a dislocation core readily provides a “short-circuit” pathway for hydrogen in-diffusion. UV-assisted or activated hydrogenation has been shown to selectively confine hydrogen to the regions associated with dislocations rather than the bulk crystal. This selectivity has not been observed during plasma-assisted hydrogenation. Charge injection during UV-irradiation is thought to provide the mechanism for limiting hydrogen in-diffusion to dislocated regions at the surface. It is believed that the injection of “hot” electrons establishes quasi-equilibrium, n-type region over their diffusion length of the electrons in the material (7-10 μm in HgCdTe.) This occurs ubiquitously in the sample except where dislocations intersect the surface. It is believed that substantial band bending occurs near the dislocation core due to pinning of the Fermi level at mid-band gap due to defects within the core. The variation of the Fermi level changes the character of hydrogen in-diffusion due to its effect on the equilibrium charge-state—which changes from H⁻ (in the n-type bulk) to H⁺ within the dislocation core. The negatively charged hydrogen is essentially immobilized in the bulk due to its size, so that little or no hydrogen in-diffusion occurs. Thus, deuterium concentration in a UV-deuterated sample will scale with the density of dislocations intersecting the surface rather than the total defect concentration. Alternatively, plasma-activated deuteration will yield deuterium levels that scale with the total defect concentration. These differences allow for the total defect concentration and the dislocation density to be measured independently. Thus, deuteration, when used as an integral part of the method disclosed herein, is a very flexible tool, which is capable of processing samples with either a UV-lamp or an indirect (remote) or direct deuterium plasma. The combined use of plasma and UV will yield a deuteration process that is both efficient (fast) and selective to dislocations. A plasma-only process is used when it is desired to deuterate the entire sample, including the defect-free regions of the bulk and the dislocation regions. The UV-enhanced method of deuteration is used when it is desired to deuterate only the dislocations regions.

To practice the preferred method disclosed herein, in one embodiment deuteration of a sample is followed by Nuclear Reaction Analysis (NRA). NRA is performed using a particle accelerator setup similar to that used for Rutherford Backscattering (RBS). Such particle accelerators are available, for example, from National Electrostatics Corporation of Middleton, Wis. Elastic scattering of ions with energy less than ˜2.0 MeV by atoms in solids forms the basis for RBS. The energy spectrum, i.e. histogram, of the backscattered ions yields both composition and structural information about the target as a function of depth. However, MeV ion beams can also induce nuclear reactions in the target nuclei. In the energy range accessible to particle accelerators used for material analysis (up to 10 MeV), this is especially the case for light projectiles impinging on light to medium heavy atoms. It is known that the yield of the prompt characteristic reaction products (γ, p, n. ³He, ⁴He, etc.) is proportional to the concentration of the specific elements in the sample. (D. J. Chemiak and W. A. Lanford, (2001) “Nuclear Reaction Analysis,” in Z. B. Alfass (Ed.), Non-Destructive Elemental Analysis. (pp. 308-375), Blackwell Publishing, New York). Absolute concentrations can be calculated with the help of standards, such as are produced by ion implantation. Therefore, NRA can be used to measure the concentration of deuterium that is present in a semiconductor using a light ion such as helium 3.

The preferred reaction for profiling D involves the use of a monoenergetic ³He beam, as given by

³He+D=α+p+18.353 MeV.

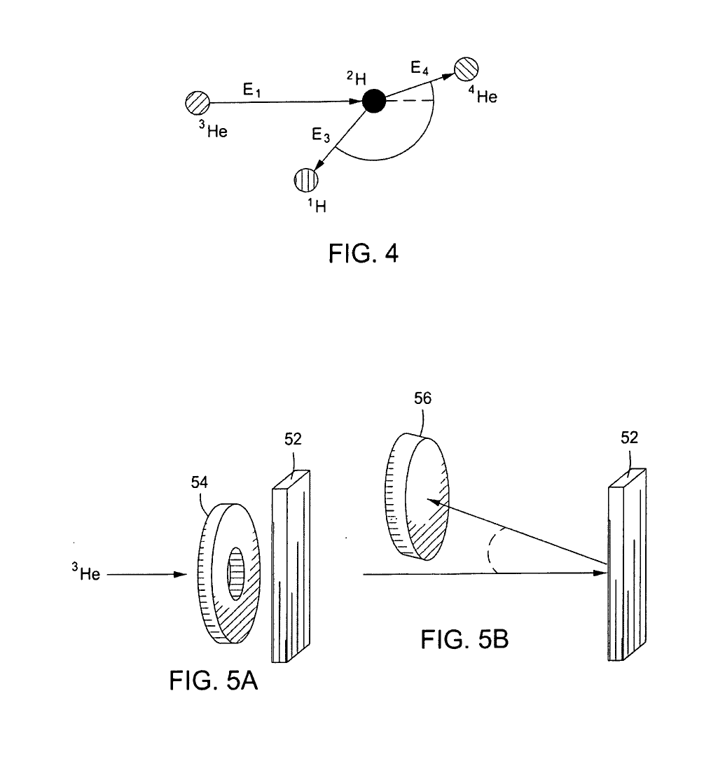

The reaction is illustrated diagrammatically by the drawing in FIG. 4, which shows the various particles involved in the nuclear reaction. The detected energy of the fast proton (E₃), as well as the reaction product, ⁴He (E₄), depends on the depth of the deuterium atom in the sample. The dependence of the detected energy of the reaction products on the reaction depth forms the basis of deuterium depth profiling. Two different detector configurations are illustrated in FIG. 5—an annular detector in FIG. 5(a) and a planar detector in FIG. 5(b). FIG. 5(a) shows an ion beam passing through a hole in annular detector 54 and impinging on deuterated sample 52. As discussed below, use of the annular design ensures a large solid-angle of detection and thus a high efficiency for counting the reaction products, as required for mapping applications. Conversely, the planar detector can be collimated to limit detection at a well-defined angle, which is required for depth profiling applications. In FIG. 5(b), planar detector 56 is used. In both configurations, an absorber foil (not shown) must be used between a detector and sample 52 to block the elastically scattered helium 3 ions to prevent overload of the detector. Both the annular and planar detectors can be standard solid-state, surface barrier designs that are commercially available from a number of vendors, such as Ortec of Oak Ridge, Tenn.

Nuclear reactions with narrow resonance energies with a resolution of the order of 10 nm can be used for depth profiling by stepping up the accelerator energy and thus shifting the depth within the target at which the reaction takes place. For example, a commonly used reaction to profile hydrogen is

¹⁵N+¹H→¹²C+α+γ(4.965 MeV).

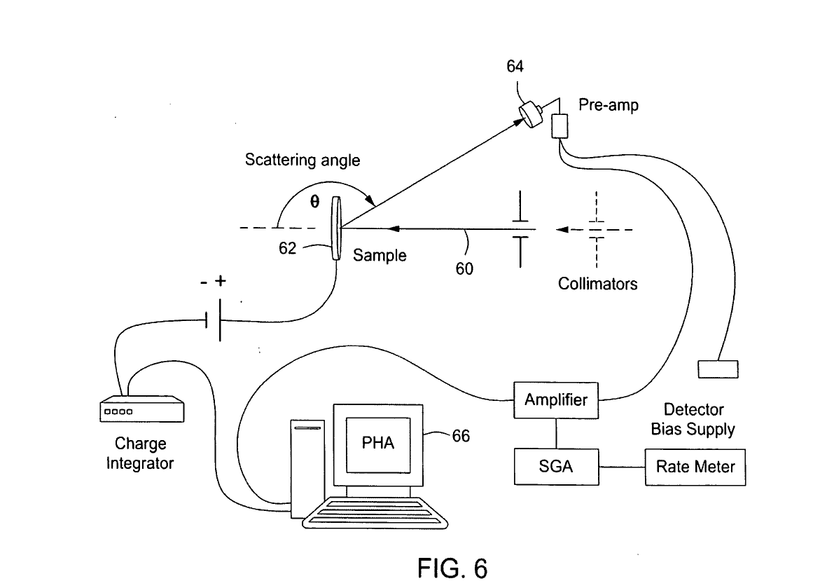

with a resonance at 6.385 MeV. The energy of the γ ray is characteristic of the reaction and the total number of gamma rays emitted is proportional to the concentration at the respective depth of hydrogen in the sample. The H concentration profile may then be obtained by increasing the ¹⁵N incident beam energy in small incremental steps. Apparatus for obtaining data for such procedure is illustrated in FIG. 6. Collimated beam 60 impinges on deuterated sample 62, producing nuclear reaction products that are detected at detector 64. The signal from detector 64 is analyzed by pulse height analyzer 66 to determine the energy spectrum of the reaction products, using well known techniques. A similar arrangement is required for D depth profiling using a non-resonant reaction such as ³He(D, ¹H)⁴He. The difference between a resonant and non-resonant reaction is related to the energy width of the reaction. A resonant reaction occurs within a very narrow energy range and yields a depth profile of deuterium by a series of measurements, which involve increasing the energy of the ion beam, i.e. ¹⁵N, in small steps. This stepping is needed to move the depth of the resonance within the sample through the deuterium distribution to construct a depth profile. Conversely, non-resonant reactions occur over a much wider energy range and therefore can be used to detect deuterium over an extended range of depth in a single measurement at constant beam energy, i.e. no stepping of the beam energy. However, an algorithm must be applied to the spectral data acquired by this method to convert it to a depth profile.

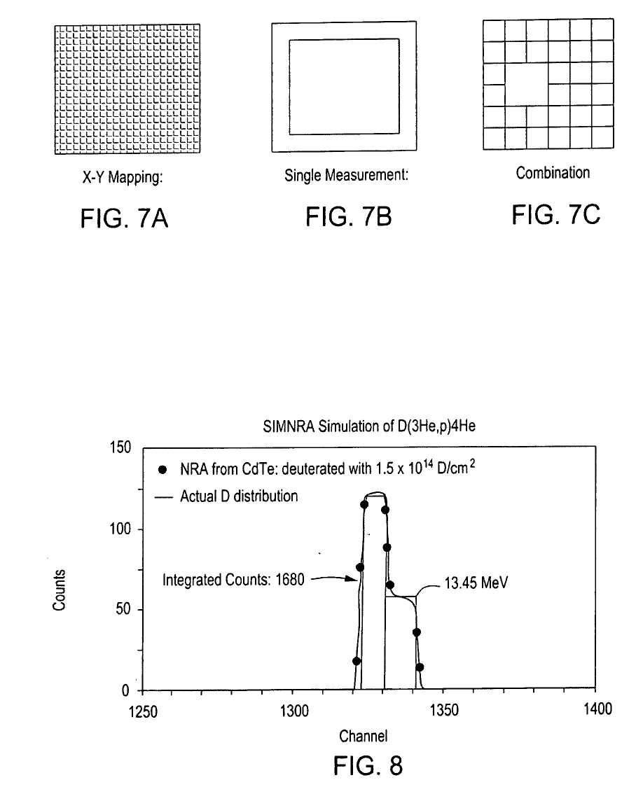

X-Y wafer mapping of the deuterium concentration in samples involves counting the total number of detector events due to the reaction products, i.e. ¹H and ⁴He, as a ³He-beam spot is stepped across the sample surface, using well known techniques. FIG. 7 illustrates some options for wafer mapping, including: a detailed X-Y mapping of the wafer surface in FIG. 7(a), which yields the most information but also is the most time consuming; use of a single measurement with a rastered beam over a large area, as shown in FIG. 7(b), which could quickly provide an average indication of the material quality; or a combined approach involving course mapping of the wafer to identify defective areas followed by a mapping these areas using a finer grid, as shown in FIG. 7(c). The approach illustrated in FIG. 7(c) may be the best approach in many cases. A spot size of ˜1 mm is anticipated for use in mapping, but smaller spot sizes, as small as 1 sq micrometer, may be used, as explained below. This process may be automated to start/stop data acquisition and to re-position the sample in-between runs to the appropriate X-Y coordinate. Since only the integrated counts need be recorded at each spot, only a single-channel analyzer is required for areal mapping. The use of integrated counts limits the beam flux on the sample and, thus, reduces the time and cost of mapping.

Scanning may be performed by stepping the wafer relative to the incident ion beam. The steps may be discrete or continuous. Since only a representation of the near-surface damage is desired during mapping, no energy analysis of the reaction products is necessary. Comparison of the total defect concentration (within a selected range of depth) across a selected area of a wafer requires only a simple counting of the reaction products. This may be done by a solid-state, surface-barrier detector, commonly used in detection of high-energy particles. A large solid-angle of detection is provided by an annular detector design as shown in FIG. 5(a), which will allow the detector to be close-coupled to the sample to ensure maximum counting efficiency. Determination of the energy of the reaction products is necessary if depth profiling of the defects is desired (as discussed below).

To evaluate the potential of using the ³He(D,p)⁴He reaction to X-Y map deuterium in CdTe, the reaction of 800 keV 3He-ions incident on a deuterated CdTe sample was simulated using SIMNRA, a computer program. (Matej Mayer, “SIMNRA Home Page 5.0,” November 2006 Sep. 13, 2007 http://www.rzg.mpg.de/˜mam/). Results are shown in FIG. 8. SIMNRA is routinely used to simulate a range of ion-solid interactions including elastic scattering (RBS), NRA, and ERDA (elastic recoil detection analysis.) The relevant parameters used in this simulation were as follows: beam current of 100 namps.; exposure time of 3 mins/spot.; ion energy of 800 keV, detector angle of 135°, total deuterium of 1.5×10¹⁴ cm⁻². The results of the simulation clearly demonstrate that NRA is able to detect low levels of deuterium in solid samples. The simulation shows that an areal density of 1.5×10¹⁴ D/cm^{2 in} CdTe will yield 1680 histogram counts during a 3 min. sample exposure to a ³He-beam at 100 namps. This corresponds to a measurement uncertainty of ±1.2%. Decreasing the exposure time to 1 min. will result in 560 counts with an uncertainty of ±2.1%. Thus, the total time for mapping a wafer surface will depend upon the desired number of evaluation sites, accuracy, and deuterium concentration within the sample. Clearly, the results indicate that deuterium mapping is possible with this technique if the number of evaluation sites can be limited to reasonable numbers, e.g. 200.

A number of ion-induced nuclear reactions for detection of hydrogen and its isotopes are listed in Table 1. While any of the reactions can be used, the ones with the largest cross-section are selected, in general, to achieve the greatest detection sensitivity.

Table 1: Example ion-induced nuclear reactions with high cross-sections for detection of hydrogen isotopes.

| | | Incident | Emitted | |
|---|---|---|---|---|
| | Q Value | energy | Energy | Approximate cross |
| Reaction | (MeV) | (MeV) | (MeV) | section in (mb/sr) |
| D(d,p)³He | 4.033 | 1.0 | 2.3 | 5.2 |
| D(³He,p)⁴He | 18.352 | 0.7 | 13.0 | 61 |
| ⁶Li(p,³He)⁴He | 4.02 | | | |
| ⁶Li(d,α)⁴He | | 0.7 | 9.7 | 35 |
| ⁷Li(p,α)⁴He | 17.347 | 1.5 | 7.7 | 9 |
| ¹¹B(p,α)⁸Be | 8.582 | 0.65 | 5.57(α₀) | 0.7 |
| | | 0.65 | 3.70(α₁) | 550 |
| ¹²C(d,p)¹³C | | 1.2 | 3.1 | 35 |
| ¹⁵N(p,α)¹²C | 4.966 | 0.8 | 3.9 | 15 |
| ¹⁸O(p,α)¹⁵N | 3.9804 | 0.73 | 3.4 | 15 |
| ¹⁹F(p,α)¹⁶O | 8.1137 | 1.25 | 6.9 | 0.5 |
| ²³Na(p,α)²⁰Ne | | 0.592 | 2.238 | 4 |
| ³¹P(p,α)²⁸Si | | 1.514 | 2.734 | 16 |

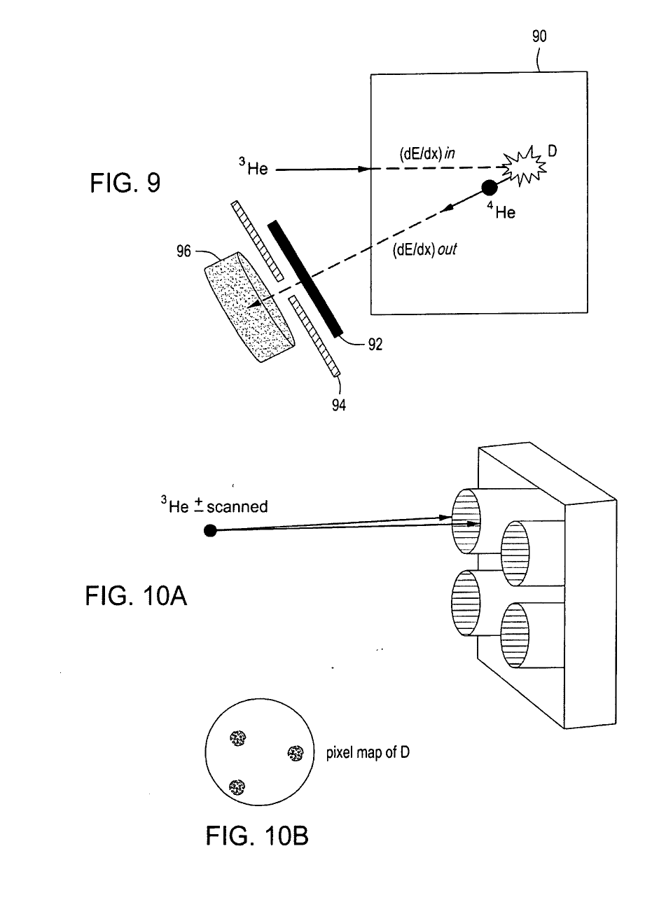

Depth profiling of defects is accomplished similarly to wafer mapping. First the defects are tagged with deuterium and then analyzed using NRA to measure the deuterium concentration. However, unlike mapping, the nuclear reaction products must be energy analyzed to determine the sample depth at which they originate. Thus the energy spectrum of the reaction products, i.e. the ⁴He product, will be converted to a histogram of defect concentration verses depth, using apparatus such as illustrated in FIG. 6 and FIG. 9. An ion beam is directed on to sample 90 (FIG. 9). The nuclear reaction occurs at a depth below the surface of 90. Absorber foil 92 is placed ahead of collimator 94 and detector 96. Solid-state, surface-barrier detector 96 will be used to record the energy spectrum of the reaction products. (FIG. 6) However, it must be positioned angularly with a small acceptance angle to ensure that a meaningful energy-to-depth conversion can be made. Energy-to-depth conversion must be done by analyzing each channel of the histogram, i.e. spectrum. Given that the spectrum can have thousands of channels, the task may be performed by a computer-based algorithm. The algorithm must consider both the energy loss of the incident ³He-ion on its inward path (dE/dx)ᵢₙ in the sample and its effect on the energy of the ⁴He reaction products, as shown in FIG. 9. Also, the subsequent energy loss of the ⁴He reaction product along its outgoing path, (dE/dx)ₒᵤₜ must be considered, as well as its energy loss in the absorber foil.

Isotopes may also be analyzed using Raman spectroscopy. Samples analyzed by Raman spectroscopy are typically excited with an Ar⁺ laser at wavelengths of 532 nm, 488 nm or 457 nm, and inelastic scattering or Stokes Raman scattering of the incident radiation is detected with a CCD detector. The probing depth for laser at a wavelength of 532 nm in HgCdTe is about 13 nm. To avoid any heating, a laser power of 10 mW or smaller is used for room temperature measurement, although higher powers can be used if samples are actively cooled. Macro- or standard-Raman may be used with a laser spot size of ˜3 mm, which is reduced down to 1 μm in diameter for micro-Raman spectroscopy. In micro-Raman, a spatial resolution of less than 1 μm can be achieved with a spectral resolution of 3 cm⁻¹ at full-width, half-maximum (FWHM).

The method disclosed herein may also be used to monitor process-induced effects in a wide variety of materials. While tools such as that available from Therma-wave (based on the paper “Ion implant monitoring with thermal wave technology,” L. Smith, A. Rosencwaig, and D. L. Wittenborg, Appl. Phys. Lett. 47 (1985) 584) have been developed for monitoring implantation and thermal processing in Si, they have not been adapted for use in compound semiconductors. Since Therma-wave technology has not demonstrated its usefulness in these materials, remediation of many process-related problems has largely been unresolved. For example, residual defects after implantation/annealing are believed to be a main contributor to diode dark current in InSb-based FPAs. Thus, the method disclosed herein can be used for monitoring ion-induced defects and their annealing behavior in InSb and other materials. Process monitoring/characterization will benefit greatly from the defect profiling capability disclosed above. Since the type and density of ion-induced defects can vary widely over the ion range, the annealing behavior often exhibits a marked depth dependence that can only be evaluated by defect profiling.

To understand the failure mechanism, the method disclosed herein may also be applied to interrogate individual pixels to determine correlations between defects within the pixel and its electrical behavior, i.e. dark current. The operability and manufacturing yield of VLWIR HgCdTe photodiode arrays are typically limited by high dark current, which can change significantly (up to a factor of 35) when the devices are thermally cycled from to room temperature and then cooled again to 40-45 K. This results in a manufacturing yield for a 256×256 two-color LWIR array that ranges between 5-25%. Higher yields can only be achieved if the underlying problems related to IRFPA manufacturing can be identified and rectified. Identification of the source of the problems can be achieved by application of a failure analysis technique as provided by the methods disclosed herein. Failure analysis can be achieved by scanning a very small diameter beam (“microbeam,” for example, 1 micrometer diameter) to map deuterium within an individual deuterated pixel to achieve an X-Y map of defects, again using NRA to reveal the deuterated defects. Such beams may be obtained, for example, by methods described in “Magnetic quadrupole doublet focusing system for high-energy ions,” Rev. of Sci. Inst. 79, 036102, 2008. The illustration in FIG. 10(a) shows the relationship of the microbeam to an interrogated pixel within a focal plane array. FIG. 10(b) illustrates a map showing defect concentration in a pixel. Further, defect mapping of a pixel may be combined with use of a microbeam to measure chemical composition within the pixel to evaluate the presence of impurities, as demonstrated by Kamio, “Microstructure and Properties of Aluminum”, Japan Institute of Light Metals, 1991, pp 201-209. The chemical identification may be achieved by particle-induced x-ray excitation (PIXE), which can be achieved with the same ion beam, i.e. ³He, as used for deuterium detection. However, a different detector than the one used for deuterium mapping (although similar in construction) may be used to detect x-rays, as is well known in the art. Elemental maps of a pixel may be obtained by this method. The use of deuterium mapping and X-ray analysis for impurities to detect both defects and chemical impurities at the pixel level can provide unprecedented information to determine the failure mode in pixels.

Failure analysis is a key to increasing yield by identification of manufacturing problems associated with low yields. This includes inherently poor manufacturing schemes or environmental factors such as contaminants including particulates and chemical impurities that limit yield. Failure analysis using the techniques described here may be included in a manufacturing process to prevent further processing of materials that will not produce the desired characteristics of a device or may be used to determine corrections that must be made to produce the desired characteristics. The identification of materials and processing problems will enhance the manufacturing yield.

Although the present invention has been described with respect to specific details, it is not intended that such details should be regarded as limitations on the scope of the invention, except to the extent that they are included in the accompanying claims.

We claim:

1. A method for detecting defects in a semiconductor material, comprising:
placing a hydrogen isotope in the semiconductor material;
measuring the concentration of the hydrogen isotope, thereby reflecting the amount of defects in the semiconductor material.

2. The method of claim 1 wherein the measure of concentration of the hydrogen isotope is obtained by directing a beam of ions onto the semiconductor material; and
measuring products of an ion-induced nuclear reaction to detect the presence of the hydrogen isotope, thereby detecting defects in the semiconductor material.

3. The method of claim 1 wherein the measure of concentration of the hydrogen isotope is obtained by a spectroscopic method.

4. The method of claim 1 whereby the hydrogen isotope is placed in the semiconductor material by placing the material in or in proximity to a hydrogen isotope plasma.

5. The method of claim 1 whereby the hydrogen isotope is placed in the semiconductor material by placing the material in a hydrogen isotope gas and irradiating the material with an ultraviolet (UV) radiation source.

6. The method of claim 1 whereby the hydrogen isotope is placed in the semiconductor material by placing the material in or in proximity to a hydrogen isotope plasma and by placing the material in a hydrogen isotope gas and irradiating the material with an ultraviolet (UV) radiation source.

7. The method of claim 1 wherein the hydrogen isotope is deuterium.

8. The method of claim 2 wherein the beam of ions comprises helium 3 ions.

9. The method of claim 2 wherein the beam of ions is directed to one or more selected areas on the semiconductor material.

10. The method of claim 8 wherein the selected areas are in a pattern selected to detect a particular type of defect.

11. The method of claim 1 wherein the semiconductor material is formed into a wafer.

12. The method of claim 1 wherein the semiconductor material is in a pixel.

13. The method of claim 2 wherein the ion beam is focused to a diameter less than about 10 microns in diameter.

14. The method of claim 2 wherein the ion beam is directed on to the material at a selected energy so as to produce a resonance reaction at a selected depth in the semiconductor material.

15. The method of claim 2 further comprising measuring an energy histogram of a product of the nuclear reaction for determining a depth distribution of lattice defects.

16. The method of claim 12 further comprising irradiating the pixel with a selected ion beam to produce X-rays and analyzing the X-rays to determine the presence of an element on the semiconductor material.

17. The method of claim 1 wherein the semiconductor is a Hg₁₋ₓCdₓTe/Hg_{1-y}Cd_{y}Te/CdTe/Si heterostructure.

18. A method for manufacturing a semiconductor product, comprising:
selecting a sample of the product during or after manufacture;
performing the method of claim 1 on the sample; and
adjusting the method of manufacture based on results of the method of claim 1.
